(19) United States
(12) Patent Application Publication
(10) Pub. No.: US 2005/0201455 A1
(43) Pub. Date: Sep. 15, 2005

(54) Equalizer architecture

(75) Inventor: Paul Wilson, Linlithgow (GB)

Correspondence Address: LAHIVE & COCKFIELD, LLP., 28 STATE STREET, BOSTON, MA, 02109, US

(73) Assignee: Phyworks Limited, Bristol (GB)

(21) Appl. No.: 10/817,206

(22) Filed: Apr. 1, 2004

(30) Foreign Application Priority Data
Mar. 15, 2004 (GB) 0405766.7

(51) Int. Cl. H03K 5/159

(52) U.S. Cl. 375/232

(57) ABSTRACT

An equalizer is divided between two tapped delay lines. One half of the sampled data is passed along one delay line, and the other half of the sampled data is passed along the other delay line. Delayed samples are passed to two summing circuits, and the output is formed from the two summing circuits alternately. This structure has the advantage that, by doubling the number of components, each component effectively only needs to operate at half the rate which would be required in a conventional structure. This allows the equalizer to operate successfully with signals at higher data rates.

### TECHNICAL FIELD OF THE INVENTION

This invention relates to an equalizer architecture, and in particular to an equalizer which can be used to compensate for the distortion introduced by a communications channel in a high data rate communications system.

### BACKGROUND OF THE INVENTION

In a conventional digital data transmission system, a sequence of data bits is transmitted over a communications medium. A receiver then attempts to recreate the transmitted sequence. That is, for each received bit, the receiver determines whether the transmitted bit is more likely to have been a ‘one’ or a ‘zero’. In doing so, the receiver must deal with the fact that the received signal will not be a perfect copy of the transmitted bit sequence, but will show the effects of changes to the waveform introduced by the communications medium, and will include an additional noise component.

For many communications media, one source of changes to the waveform is inter-symbol-interference (ISI). That is, energy from one bit period is received in another bit period. In the case of optical fibres, one cause of ISI is the fact that components of optical signals travel along an optical fibre at different speeds.

The presence of ISI greatly increases the probability that the receiver will fail to determine correctly whether a specific transmitted bit was a ‘one’ or a ‘zero’. That is, it greatly increases the probability of bit errors.

It is known that it is possible to compensate for ISI to some extent. A particular transmitted waveform results in a particular received waveform, and the relationship between the transmitted waveform and the received waveform can be expressed mathematically as a transfer function. An equalizer can be provided in the receiver, which applies a second transfer function to the received waveform. If the second transfer function can be made to approximate the inverse of the first transfer function, then the effects of ISI can be approximately compensated.

Conventional equalization techniques include finite impulse response filtering, also known as feedforward equalization and transversal filtering, and decision feedback equalization.

In the first of these techniques, a received signal is sampled and passed along a tapped delay line. An output is then formed as the weighted sum of sample values at the sequence of tap points. The output is then passed to a quantizer or other decision device to determine whether the received signal at a given point in time represents a transmitted ‘1’ or a transmitted ‘0’.

A decision feedback equalizer operates in the same way, except that the input value is passed along the tapped delay line only as far as a central tap point, and thereafter it is the quantizer output value which is passed along the tapped delay line.

A disadvantage with such equalizers, in particular in the case of fibre optic receivers operating at data rates of, for example, 10 Gbps or more, is that they place a high computational burden on the components.

### SUMMARY OF THE INVENTION

It is an object of the present invention to provide an equalizer architecture which can be used with received data signals at very high data rates, without placing such a high computational burden on the components of the device.

In accordance with an aspect of the present invention, there is provided an equalizer comprising: a first tapped delay line, for receiving samples of an input signal at a first series of time points; a second tapped delay line, for receiving samples of an input signal at a second series of time points, wherein successive time points alternate the first and second series of time points; a first summing circuit, for forming a first output as a weighted sum of sample values from a first series of tap points in the first tapped delay line and a first series of tap points in the second tapped delay line, wherein tap points in the first series of tap points in the first tapped delay line are at delays intermediate between the delays of successive tap points in the first series of tap points in the second tapped delay line; a second summing circuit, for forming a second output as a weighted sum of sample values from a second series of alternate tap points in the first tapped delay line and a second series of alternate tap points in the second tapped delay line, wherein the respective first and second series of tap points each alternate in the first and second tapped delay lines, and wherein tap points in the second series of tap points in the first tapped delay line are at delays intermediate between the delays of successive tap points in the second series of tap points in the second tapped delay line; an output, for forming an equalizer output signal from the first output at a third series of time points, and from the second output at a fourth series of time points, wherein the third and fourth series of time points alternate.

This structure has the advantage that, by doubling the number of components, each component effectively only needs to operate at half the rate which would be required in a conventional structure. This allows the equalizer to operate successfully with signals at higher data rates.

In a preferred embodiment, the first tapped delay line comprises a first plurality of controllable memory elements, and the second tapped delay line comprises a second plurality of controllable memory elements, each of the controllable memory elements alternating between time periods in which its output is static and time periods in which its output may be in transition.

In a further preferred embodiment, the controllable memory elements are controlled such that the outputs of the first series of tap points in the first tapped delay line and the first series of tap points in the second tapped delay line are static at the third series of time points, and such that the outputs of the second series of tap points in the first tapped delay line and the second series of tap points in the second tapped delay line are static at the fourth series of time points.

In another embodiment of the invention, the equalizer takes the form of a decision feedback equalizer, with the input signal being fed along respective first parts of the first and second tapped delay lines, and a decision output signal being fed along respective second parts of the first and second tapped delay lines.

### BRIEF DESCRIPTION OF DRAWINGS

FIG. 1 is a block schematic diagram of an equalizer in accordance with a first embodiment of the present invention.

FIGS. 2a and 2b are timing diagrams showing signals propagating through the equalizer of FIG. 1 at various time points.

FIG. 3 is a block schematic diagram of an equalizer in accordance with an alternative embodiment of the invention.

### DETAILED DESCRIPTION OF PREFERRED EMBODIMENTS

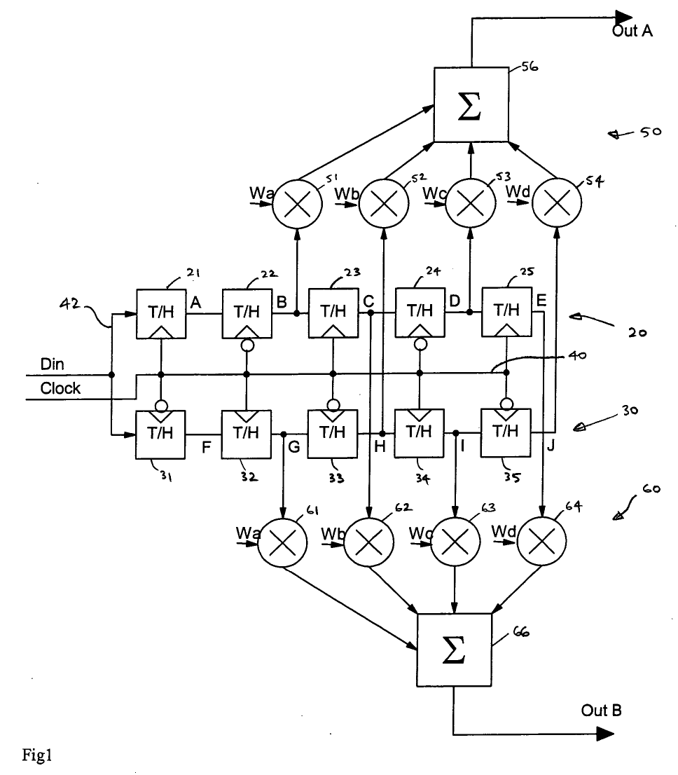

FIG. 1 is a block schematic diagram of an equalizer in accordance with the present invention, implemented in the form of a finite impulse response filter, divided into two parallel paths.

Thus, compared with a conventional finite impulse response filter implementation, which includes a tapped delay line, the equalizer of FIG. 1 includes a first tapped delay line 20 and a second tapped delay line 30. In this illustrated embodiment of the invention, the first tapped delay line 20 is made up of five track and hold circuits 21-25, while the second tapped delay line 30 is made up of five track and hold circuits 31-35. However, it will be appreciated that the tapped delay lines may be of any convenient length, depending on the extent to which transmitted bits are spread over multiple bit periods by the time they reach the receiver.

In this illustrated embodiment of the invention, each of the track and hold circuits 21-25, 31-35 is of a type which is transparent when its clock signal input is high, and holds the value when its clock signal input is low. Thus, each of the track and hold circuits 21-25, 31-35 has a clock signal input. While the clock signal at this input is high, the value at the input of the track and hold circuit is passed through to its output, and this output value then remains fixed at the input value when the falling clock signal transition occurs.

The clock signal is supplied along a clock signal supply line 40 to each of the track and hold circuits 21-25, 31-35. However, while the clock signal is supplied unchanged to the first, third and fifth track and hold circuits 21, 23, 25 in the first tapped delay line 20, and to the second and fourth track and hold circuits 32, 34 in the second tapped delay line 30, it is supplied inverted to the second and fourth track and hold circuits 22, 24 in the first tapped delay line 20, and to the first, third and fifth track and hold circuits 31, 33, 35 in the second tapped delay line 30.

The received signal, Din, which may for example be supplied along an optical fibre at a high data rate, is received after conversion from an optical signal to an electronic signal, on a data input line 42, and is applied initially to the inputs of the first track and hold circuits 21, 31 in each of the tapped delay lines 20, 30.

Together with the first and second tapped delay lines 20, 30, this embodiment of the present invention also includes first and second weighted summing blocks 50, 60. Each of the weighted summing blocks 50, 60 forms the weighted sum of a respective series of output values of the track and hold devices.

Thus, the first weighted summing block 50 multiplies the output of the second track and hold block 22 from the first tapped delay line 20 by a first weighting coefficient Wa in a first multiplier 51; multiplies the output of the third track and hold circuit 33 in the second tapped delay line 30 by a second weighting coefficient Wb in a second multiplier 52; multiplies the output of the fourth track and hold circuit 24 in the first tapped delay line 20 by a third weighting coefficient Wc in a third multiplier 53; and multiples the output of the fifth track and hold circuit 35 in the second tapped delay line 30 by a fourth weighting coefficient Wd in a fourth multiplier 54. The outputs of the multipliers 51-54 are then added in a summing block 56 to form a first output value, Out A.

Similarly, the second weighted summing block 60 multiplies the output of the second track and hold block 32 from the second tapped delay line 30 by the first weighting coefficient Wa in a first multiplier 61; multiplies the output of the third track and hold circuit 23 in the first tapped delay line 20 by the second weighting coefficient Wb in a second multiplier 62; multiplies the output of the fourth track and hold circuit 34 in the second tapped delay line 30 by the third weighting coefficient Wc in a third multiplier 63; and multiples the output of the fifth track and hold circuit 25 in the first tapped delay line 20 by a fourth weighting coefficient Wd in a fourth multiplier 64. The outputs of the multipliers 61-64 are then added in a summing block 66 to form a second output value, Out B.

The first and second output values, Out A, Out B, can be binary values, or can be multi-level values.

Thus, the first summing circuit forms the weighted sum of a first series of alternate sample values from the first tapped delay line and a first series of alternate sample values from the second tapped delay line, while the second summing circuit forms the weighted sum of a second series of alternate sample values from the first tapped delay line and a second series of alternate sample values from the second tapped delay line, with the first and second series in each tapped delay line alternating with each other. Also, sample values at corresponding positions in the first and second tapped delay lines are supplied to different summing circuits.

The first and second output signals are then combined to form an overall output signal. Thus, during one half of each clock period of the input clock signal, the value of the combined output signal is taken from the first output signal, Out A, while, during a second half of each clock period of the input clock signal, the overall output value is taken from the value of the second output signal, Out B.

There is therefore provided an equalizer architecture which can provide an overall output signal having a data rate which is twice the clock signal frequency, and which is therefore able to handle a received input signal having a frequency which is twice the clock signal frequency. For example, in a preferred embodiment of the invention, in which the received signal has a data rate of 10 Gbps, it is only necessary to use a clock signal having a frequency of 5 GHz, and the track and hold circuits 21-25, 31-35, multipliers 51-54, 61-64 and adders 56, 66 only need to operate at this lower frequency.

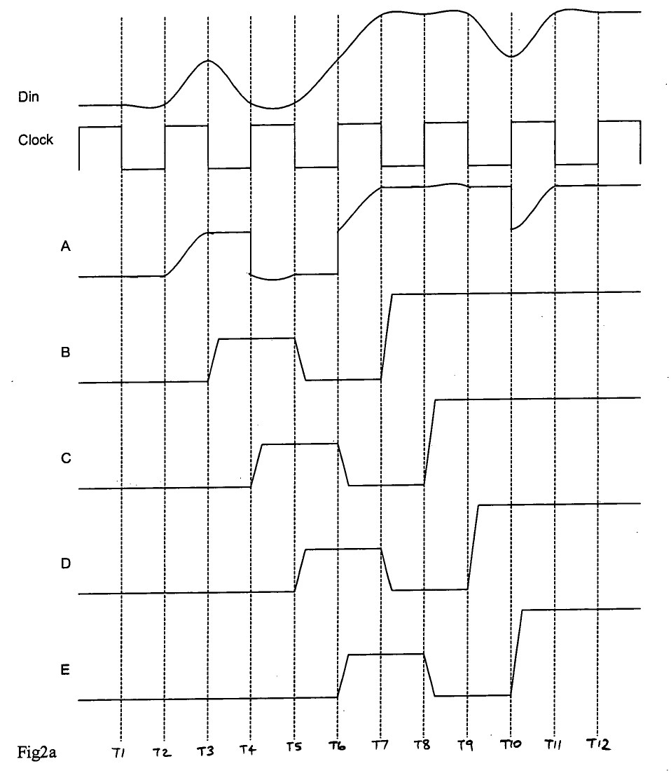

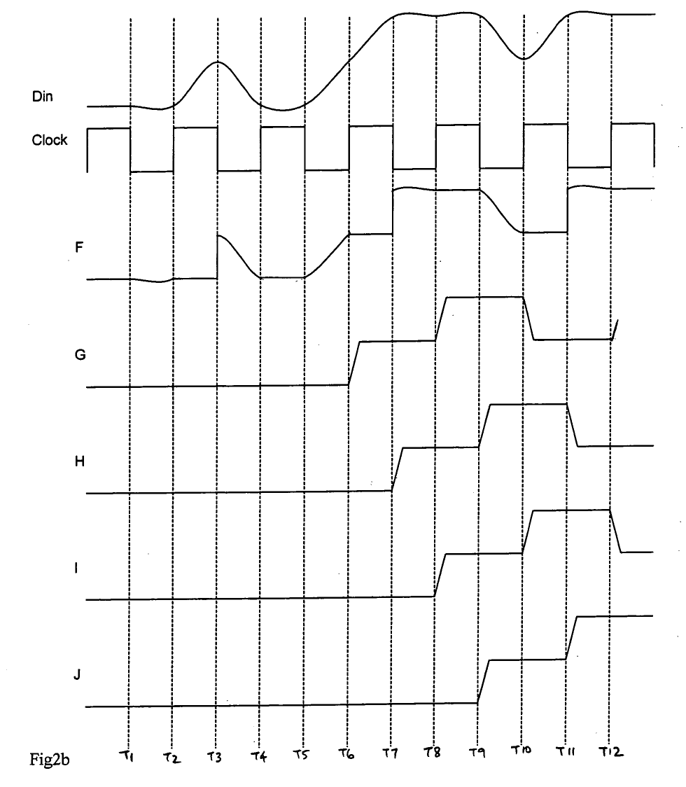

FIGS. 2a and 2b are timing diagrams, illustrating the operation of the circuit of FIG. 1. Specifically, FIG. 2a shows the time history of the input signal Din, and schematic representations of the signals at points A, B, C, D and E, at the outputs of the first, second, third, fourth and fifth track and hold circuits 21-25 of the first tapped delay line 20, in the lines marked A, B, C, D and E respectively, over a time period extending over times T1-T12. FIG. 2b shows the time history of the input signal Din, and schematic representations of the signals at points F, G, H, I and J, at the outputs of the first, second, third, fourth and fifth track and hold circuits 31-35 of the second tapped delay line 30, in the lines marked F, G, H, I and J, over the same time period.

As mentioned above, each of the track and hold circuits 21-25, 31-35 passes its input value through to its output while its clock signal input is high, and this output value then remains fixed while its clock signal input is low. Also, the clock signal is supplied unchanged to the first, third and fifth track and hold circuits 21, 23, 25 in the first tapped delay line 20, and to the second and fourth track and hold circuits 32, 34 in the second tapped delay line 30, but is supplied inverted to the second and fourth track and hold circuits 22, 24 in the first tapped delay line 20, and to the first, third and fifth track and hold circuits 31, 33, 35 in the second tapped delay line 30.

Therefore, considering line A in FIG. 2a as an example, during the time period T1-T2, the output of the first track and hold block 21 in the first tapped delay line 20 remains constant, but during the time period T2-T3 it tracks the input of that block. That is, it tracks the value of Din. During the time period T3-T4, the output of the first track and hold block 21 in the first tapped delay line 20 remains constant, at the value it took at time T3. Thereafter, during the time period T4-T5, the output of the first track and hold block 21 in the first tapped delay line 20 resumes tracking the value of Din, and then during the time period T5-T6, the output of the first track and hold block 21 in the first tapped delay line 20 remains constant, at the value it took at time T5.

Considering line B in FIG. 2a as a second example, the second track and hold block 22 in the first tapped delay line 20 receives the clock signal inverted. The result is that, during the time period T1-T2, the output of the second track and hold block 22 in the first tapped delay line 20 tracks the output value of the first track and hold block 21. During the time period T2-T3 it remains constant, and then during the time period T3-T4 the output of the second track and hold block 22 in the first tapped delay line 20 reacts to and then tracks the output value of the first track and hold block 21. During the time period T4-T5, the output of the second track and hold block 22 in the first tapped delay line 20 remains constant, at the value it took at time T4. Thereafter, during the time period T5-T6, the output of the second track and hold block 22 in the first tapped delay line 20 resumes tracking its input value, that is, the output value of the first track and hold block 21. During the time period T6-T7, the output of the second track and hold block 22 in the first tapped delay line 20 remains constant, at the value it took at time T6.

Considering line F in FIG. 2b as a third example, the first track and hold block 31 in the second tapped delay line 30 receives the clock signal inverted. The result is that, during the time period T1-T2, the output of the first track and hold block 31 in the second tapped delay line 30 tracks its input value, namely the input signal Din. During the time period T2-T3 it remains constant, and then during the time period T3-T4 the output of the first track and hold block 31 in the second tapped delay line 30 reacts to and then tracks the input signal Din. During the time period T4-T5, the output of the first track and hold block 31 in the second tapped delay line 30 remains constant, at the value it took at time T4. Thereafter, during the time period T5-T6, the output of the first track and hold block 31 in the second tapped delay line 30 resumes tracking its input value, that is, the input signal Din. During the time period T6-T7, the output of the first track and hold block 31 in the second tapped delay line 30 remains constant, at the value it took at time T6.

The same analysis can be repeated for all of the track and hold blocks for all times. However, it is relevant to note that the value of Din at each falling clock transition is effectively sampled, and passed along the first delay line 20, with each of the track and hold blocks 22-25 effectively delaying the signal by one half of a clock period. By contrast, the value of Din at each rising clock transition is effectively sampled, and passed along the second delay line 30, with each of the track and hold blocks 32-35 effectively delaying the signal by one half of a clock period. In effect, the input signal Din is demultiplexed, with samples taken twice per clock period, and one half of the samples propagating along the first delay line 20, and the other half of the samples propagating along the second delay line 30.

Each of the track and hold blocks 22-25, 32-35 spends one half of each clock cycle reacting to, and then tracking, its input, and then spends the other half of each clock cycle static. In this illustrated embodiment the track and hold blocks 21, 23, 25, 32, 34 are in transition while the clock signal is high (that is, during time periods T2-T3, T4-T5, etc), and are static while the clock signal is low (that is, during time periods T1-T2, T3-T4, etc). Conversely, the track and hold blocks 22, 24, 31, 33, 35 are in transition while the clock signal is low (that is, during time periods TI-T2, T3-T4, etc), and are static while the clock signal is high (that is, during time periods T2-T3, T4-T5, etc).

The summing circuits 50, 60 then operate to produce an output signal twice per clock cycle. At each point, one of the summing circuits produces an output signal based on the outputs of the track and hold blocks which are static. That is, while the clock signal is high, the first summing circuit 50 produces an output signal based on the static outputs of the track and hold blocks 22, 24, 33 and 35. Conversely, while the clock signal is low, the second summing circuit 60 produces an output signal based on the static outputs of the track and hold blocks 23, 25, 32 and 34.

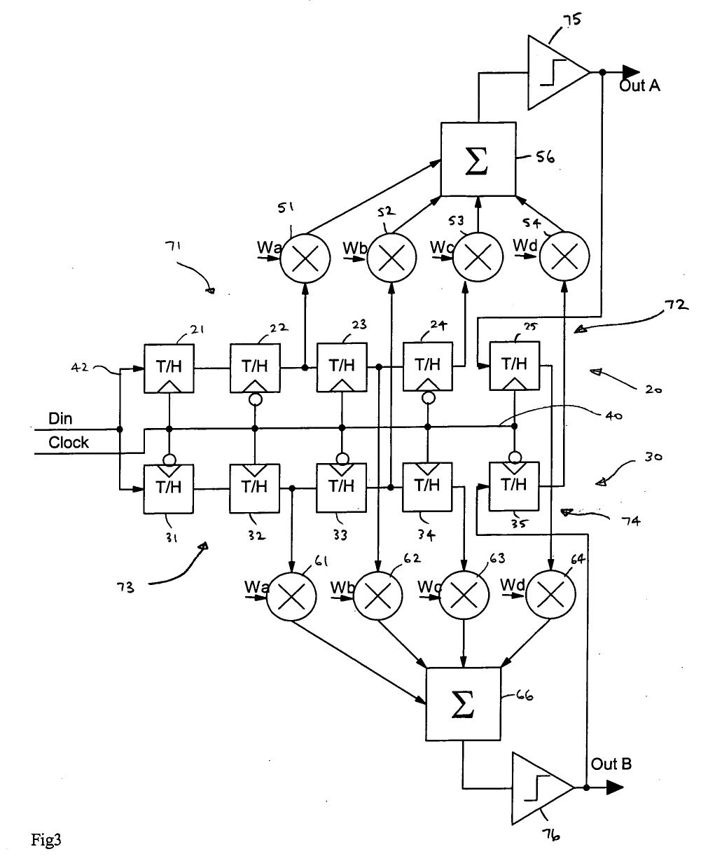

FIG. 3 is a block schematic diagram of an alternative embodiment of an equalizer in accordance with the present invention. More specifically, FIG. 3 is a block schematic diagram of an equalizer in accordance with the present invention, implemented in the form of a decision feedback equalizer.

The decision feedback equalizer of FIG. 3 operates in generally the same way as a conventional decision feedback equalizer, except that it is divided into two parallel paths, just as the finite impulse response filter of FIG. 1 is divided into two parallel paths.

Features of the decision feedback equalizer of FIG. 3, which have the same functions as features of the finite impulse response filter of FIG. 1, are indicated by the same reference numerals, and will not be described further herein.

In the equalizer of FIG. 3, the first tapped delay line 20 is divided into a first part 71, which includes the first four track and hold circuits 21-24, and a second part 72, which contains the final track and hold circuit 25. Thus, the first part 71 includes the track and hold circuits up to and including the one whose output is supplied to the central multiplier 53. Similarly, the second tapped delay line 30 is divided into a first part 73, which includes the first four track and hold circuits 31-34, and a second part 74, which contains the final track and hold circuit 35. Thus, the first part 73 includes the track and hold circuits up to and including the one whose output is supplied to the central multiplier 63.

FIG. 3 also shows that the outputs from the summing circuits 56, 66 are applied to respective decision devices 75, 76. As shown in FIG. 3, the decision devices 75, 76 are slicers, that is, all inputs below a threshold value are assigned the output value “0”, while all inputs above the threshold value are assigned the output value “1”.

The received signal Din is then passed along the first parts 71, 72 of the first and second tapped delay lines 20, 30. The output from the first slicer 75 is fed back into the second part of the first tapped delay line 20, while the output from the second slicer 76 is fed back into the second part of the second tapped delay line 30. The result is that it is the quantized output signals which are used to cancel any interference arising from the earlier transmitted bits.

Since the track and hold circuits 25, 35 in the second parts 72, 74 of the first and second delay lines 20, 30 receive only binary valued inputs, they can be in the form of binary circuits, such as D-type flip-flops.

Although FIG. 3 shows slicers 75, 76, which generate binary values for the first and second output values, Out A, Out B, these can be replaced by quantizers which generate multi-level values for the first and second output values, Out A, Out B. In that case, the track and hold circuits 25, 35 in the second parts 72, 74 of the first and second delay lines 20, 30 must be able to handle these multi-level values as inputs.

Again, the effect of dividing the equalizer structure into two parallel paths is that the overall output signal has a data rate which is twice the clock signal frequency, and that the structure is therefore able to handle a received input signal having a frequency which is twice the clock signal frequency. For example, in a preferred embodiment of the invention, in which the received signal has a data rate of 10 Gbps, it is only necessary to use a clock signal having a frequency of 5 GHz, and the track and hold circuits 21-25, 31-35, multipliers 51-54, 61-64 and adders 56, 66 only need to operate at this lower frequency.

The invention has been described herein with reference to preferred embodiments in which the equalizer structure is divided into two parallel paths, with the result that the equalizer can handle a received signal having a data rate which is twice the clock signal frequency. However, the invention is more generally applicable to equalizers divided into multiple parallel paths. Where there are N such parallel paths, the sampled input signal can be demultiplexed into N separate signals, such that each Nth input sample is clocked along a respective one of the parallel paths. The taps along each delay line are then connected in a N-way round robin fashion to N summing elements, and each Nth bit in the overall output signal is obtained from the respective summing element. This has the result that the equalizer can handle a received signal having a data rate which is N times the clock signal frequency.

The track and hold circuits 21-25, 31-35 in the delay lines 20, 30 of the FIG. 1 embodiment, and the track and hold circuits 21-24, 31-34 in the respective first parts 71, 72 of the delay lines 20, 30 of the FIG. 3 embodiment, are analog track and hold circuits, which pass analog representations of the signals at the sampling points. However, these can be replaced if required by digital sample and hold circuits, which pass multi-bit digital representations of the signals.

There are thus provided equalizer architectures which can handle high data rate received signals, without requiring the use of correspondingly high clock rates.

1. An equalizer comprising:
a first tapped delay line, for receiving samples of an input signal at a first series of time points,
a second tapped delay line, for receiving samples of an input signal at a second series of time points, wherein successive time points alternate between the first and second series of time points,
a first summing circuit, for forming a first output as a weighted sum of sample values from a first series of tap points in the first tapped delay line and a first series of tap points in the second tapped delay line, wherein tap points an the first series of tap points in the first tapped delay line are at delays intermediate between the delays of successive tap points in the first series of tap points in the second tapped delay line,
a second summing circuit, for forming a second output as a weighted sum of sample values from a second series of tap points in the first tapped delay line and a second series of tap points in the second tapped delay line, wherein the respective first and second series of tap points each alternate in the first and second tapped delay lines, and wherein tap points in the second series of tap points in the first tapped delay line are at delays intermediate between the delays of successive tap points in the second series of tap points in the second tapped delay line,
an output, for forming an equalizer output signal from the first output at a third series of time points, and from the second output at a fourth series of time points, wherein the third and fourth series of time points alternate.

2. An equalizer as claimed in claim 1, wherein the first tapped delay line comprises a first plurality of controllable memory elements, and the second tapped delay line comprises a second plurality of controllable memory elements, each of the controllable memory elements alternating between time periods in which its output is static and time periods in which its output may be in transition.

3. An equalizer as claimed in claim 2, wherein the controllable memory elements are controlled such that the outputs of the first series of tap points in the first tapped delay line and the first series of tap points in the second tapped delay line are static at the third series of time points, and such that the outputs of the second series of tap points in the first tapped delay line and the second series of tap points in the second tapped delay line are static at the fourth series of time points.

4. An equalizer as claimed in claim 1, wherein the first tapped delay line comprises a first plurality of track and hold circuits, and the second tapped delay line comprises a second plurality of track and hold circuits, and
wherein track and hold circuits preceding the first series of tap points in the first tapped delay line and track and hold circuits preceding the first series of tap points in the second tapped delay line are clocked by a first clock signal, track and hold circuits preceding the second series of tap points in the first tapped delay line and track and hold circuits preceding the second series of tap points in the second tapped delay line are clocked by a second clock signal, wherein the second clock signal is the inverse of the first clock signal.

5. An equalizer as claimed in claim 1 comprising:
a number N of tapped delay lines, wherein N>2, for receiving samples of the input signal in sequence,
a number N of summing circuits, for forming respective outputs as weighted sums of sample values from a respective series of points arranged sequentially in the tapped delay lines,
an output, for forming the equalizer output signal from the outputs of the summing circuits sequentially.

6. An equalizer as claimed in claim 1, wherein the first tapped delay line comprises a first series of analog track and hold circuits, and the second tapped delay line comprises a second series of analog track and hold circuits.

7. An equalizer as claimed in claim 1, wherein the first tapped delay line comprises a first series of digital sample and hold circuits, and the second tapped delay line comprises a second series of digital sample and hold circuits.

8. An equalizer as claimed in claim 1, in the form of a decision feedback equalizer, further comprising:
decision circuits for forming first and second binary outputs from the first and second outputs,
a second part of said first tapped delay line, for receiving the first binary output as an input thereto,
a second part of said second tapped delay line, for receiving the second binary output as an input thereto,
wherein the first summing circuit forms the first output as a weighted sum of sample values from a first series of alternate points in the first tapped delay line including the second part of said first tapped delay line and a first series of alternate points in the second tapped delay line including the second part of said second tapped delay line, and
wherein the second summing circuit forms the second output as a weighted sum of sample values from a second series of alternate tap points in the first tapped delay line including the second part of said first tapped delay line and a second series of alternate tap points in the second tapped delay line including the second part of said second tapped delay line.

9. An equalizer as claimed in claim 8, wherein the first tapped delay line comprises a first plurality of controllable memory elements, and the second tapped delay line comprises a second plurality of controllable memory elements, each of the controllable memory elements alternating between time periods in which its output is static and time periods in which its output may be in transition.

10. An equalizer as claimed in claim 9, wherein the controllable memory elements are controlled such that the outputs of the first series of tap points in the first tapped delay line and the first series of tap points in the second tapped delay line are static at the third series of time points, and such that the outputs of the second series of tap points in the first tapped delay line and the second series of tap points in the second tapped delay line are static at the fourth series of time points.

11. An equalizer as claimed in claim 8, wherein the first tapped delay line comprises a first plurality of track and hold circuits, and the second tapped delay line comprises a second plurality of track and hold circuits, and
wherein track and hold circuits preceding the first series of tap points in the first tapped delay line and track and hold circuits preceding the first series of tap points in the second tapped delay line are clocked by a first clock signal, track and hold circuits preceding the second series of tap points in the first tapped delay line and track and hold circuits preceding the second series of tap points in the second tapped delay line are clocked by a second clock signal, wherein the second clock signal is the inverse of the first clock signal.

12. An equalizer comprising a plurality of tapped delay lines, for receiving received sample values in sequence, and a corresponding plurality of summing circuits, such that an output signal is formed from an output of each of the plurality of summing circuits in sequence.

13. An equalizer, comprising:
an input, for demultiplexing alternate samples of a received signal into first and second data streams;
a first tapped delay line, connected to receive the first data stream, and comprising a first plurality of controllable memory elements;
a second tapped delay line, connected to receive the second data stream, and comprising a second plurality of controllable memory elements; and
an output,
wherein each of the controllable memory elements alternates between time periods in which its output is static and time periods in which its output may be in transition,
wherein the controllable memory elements in the first tapped delay line are alternately members of a first group of controllable memory elements whose outputs are static during first time periods and may be in transition during second time periods, alternating with the first time periods, and a second group of controllable memory elements whose outputs are static during second time periods and may be in transition during first time periods,
wherein the controllable memory elements in the second tapped delay line are alternately members of a third group of controllable memory elements whose outputs may be in transition during first time periods and are static during second time periods, and a fourth group of controllable memory elements whose outputs are static during first time periods and may be in transition during second time periods, and
wherein the output receives a weighted sum of the outputs of the controllable memory elements of the first and fourth groups during first time periods, and receives a weighted sum of the outputs of the controllable memory elements of the second and third groups during second time periods.

14. An equalizer as claimed in claim 13, wherein the output comprises a first summing circuit for forming the weighted sum of the outputs of the controllable memory elements of the first and fourth groups, and a second summing circuit for forming the weighted sum of the outputs of the controllable memory elements of the second and third groups, and wherein the output is adapted to supply the output of the first summing circuit as an output during first time periods and to supply the output of the second summing circuit as an output during second time periods.

15. An equalizer as claimed in claim 13, comprising means for supplying a clock signal to the controllable memory elements of the first and fourth groups, and for supplying an inverted clock to the controllable memory elements of the second and third groups.

16. An equalizer as claimed in claim 13, wherein the controllable memory elements comprise analog track and hold circuits.

17. An equalizer as claimed in claim 13, wherein the controllable memory elements comprise digital track and hold circuits.

18. An optical receiver, comprising:
means for converting a received optical signal to an electronic signal; and
an equalizer as claimed in any preceding claim, connected to receive the electronic signal as an input thereto.
